(19) United States
(12) Patent Application Publication
(10) Pub. No.: US 2002/0182807 A1
(43) Pub. Date: Dec. 5, 2002

(54) Semiconductor device and method of manufacturing same

(76) Inventor: Guido Jozef Maria Dormans, Nijmegen (NL)

Correspondence Address: Corporate Patent Counsel, U.S. Philips Corporation, 580 White Plains Road, Tarrytown, NJ, 10591, US

(21) Appl. No.: 10/125,525

(22) Filed: Apr. 18, 2002

(30) Foreign Application Priority Data
Apr. 23, 2001 (EP) 01201459.3

(51) Int. Cl. H01L 21/336

(52) U.S. Cl. 438/257

(57) ABSTRACT

The invention relates to a semiconductor device comprising a semiconductor body (10) which is provided with an active semiconductor region (12) which borders on a surface (11) of said semiconductor body, which active semiconductor region is provided with a non-volatile memory cell comprising a source zone and a drain zone (29), a select gate (18), and a stacked gate structure (32) comprising a floating gate (26) and a control gate (25). The stacked gate extends above the select gate and covers a side wall (33) of said select gate, which side wall extends at least substantially perpendicularly to the surface of the semiconductor body. The stacked gate structure is insulated from the select gate by a layer of an insulating material (19, 35) that is applied to the select gate. The select gate and the floating gate, viewed along the surface of the semiconductor body, are situated at a distance from each other, which distance is determined by the thickness of the layer of insulating material applied to the select gate's side wall (33) which extends at least substantially perpendicularly to the surface of the semiconductor body, which thickness enables a continuous channel to be formed between the source zone and the drain zone.

The invention relates to a semiconductor device comprising a semiconductor body including an active semiconductor region which borders on a surface of said semiconductor body and which is provided with a non-volatile memory cell comprising a source region, a drain region, a select gate, and a stacked gate structure comprising a floating gate and a control gate, which stacked gate structure projects beyond the select gate and covers the wall of the select gate that extends at least substantially transversely to the surface, said stacked gate structure being insulated from the select gate by a layer of an insulating material. The invention also relates to a method of manufacturing such a device.

In this semiconductor device, the stacked gate structure of a memory transistor overlaps the select gate of a select transistor. By virtue thereof, the memory cell can be formed on a comparatively small part of the surface of the semiconductor body, while the stacked gate structure occupies a comparatively large surface area. A comparatively large stacked gate structure has the advantage that a comparatively large capacitive coupling is possible between the control gate and the floating gate, as a result of which the memory cell can be read using low voltages.

U.S. Pat. No. 5,550,073 discloses a semiconductor device of the type mentioned in the opening paragraph, wherein, viewed along the surface, between the select gate of the select transistor and the floating gate of the memory transistor, there is formed, in the active region, a connection region which borders on the surface and is of opposite conductivity type to the active region. During reading such a memory cell, this connection region interconnects inversion regions that are formed, in the active region, below the select gate and below the floating gate. As the connection region is present between the inversion regions, the electric resistance between the inversion regions is minimal. As a result, during reading at a low voltage, there is a comparatively high, readily detectable current flow. A drawback of the connection region is, however, that it occupies a comparatively large surface area, as a result of which the memory cell is comparatively large.

It is an object of the invention to provide a semiconductor device comprising a memory cell which can be formed on a smaller part of the surface than the memory cell of the known semiconductor device described hereinabove.

To achieve this, the semiconductor device mentioned in the opening paragraph is characterized in that the select gate and the floating gate, viewed along the surface, are situated at a distance from each other that is determined by the thickness of the layer of insulating material applied to the wall of the select gate, said wall extending substantially transversely to the surface, and said thickness enabling a continuous channel to be formed between the source region and the drain region. Surprisingly, it has been found that the thickness of the layer of insulating material against the select gate wall extending at least substantially transversely to the surface, which thickness determines the distance between the select gate and the floating gate, can be chosen to be such that a connection region as used in the known memory cell described hereinabove can be dispensed with. By virtue thereof a substantial gain in space is achieved. Despite the absence of this connection region, it has been found that the inversion regions, which are formed during reading of the memory cell below the select gate and below the floating gate in the active semiconductor region, blend so well with each other that a negligibly small series resistance is present between said inversion regions, resulting in a continuous channel between the source region and the drain region. At a read voltage between 0.5 and 1 volt, a read current ranging between 30 and 50 μA is generated which can be readily detected in practice. In this respect, it is advantageous if the thickness of the layer of insulating material against the select gate wall extending at least substantially transversely to the surface is smaller than 70 nm. Preferably, this thickness is smaller than 50 nm and larger than 30 nm. The distance between the select gate and the floating gate preferably is not below 30 nm to avoid excessive parasitic coupling between the select gate and the floating gate. As a result of such parasitic coupling, writing data in and erasing data from the memory cell would be less effective. At an equal voltage on the control gate, the voltage difference between the floating gate and the underlying active semiconductor region would be smaller. As a result, writing and erasing data would take longer. To compensate this, the memory would have to be operated at higher write and erase voltages, which is undesirable.

In order to further reduce said parasitic coupling, the layer of insulating material is provided on the select gate in a thickness that is preferably larger than the thickness of the layer of insulating material against the select gate wall extending at least substantially transversely to the surface. By virtue thereof, parasitic coupling is reduced while the distance between the select gate and the floating gate can be maintained at a value that enables a continuous channel to be formed. In practice, said parasitic coupling is negligibly small if the layer of insulating material on top of the select gate has a thickness above 100 nm.

The invention also relates to a method of manufacturing a semiconductor device comprising a non-volatile memory cell, wherein

a semiconductor body is provided, at a surface, with an active semiconductor region;

a select gate is provided, which select gate is insulated from the active semiconductor region;

the select gate is provided with a layer of an insulating material;

a stacked gate structure comprising a floating gate and a control gate is provided, which stacked gate structure extends above the select gate and covers the select gate wall extending at least substantially transversely to the surface, which stacked gate structure is insulated from the select gate by means of the layer of insulating material and insulated from the active semiconductor region by means of a gate dielectric;

the active semiconductor region is provided with a source region and a drain region, the select gate and the stacked gate structure being used as a mask.

Such a method is disclosed in the above-mentioned U.S. Pat. No. 5,550,073, wherein, after the formation of the select gate, first the connection region is formed. Subsequently, the stacked gate structure is formed. To form the connection region, a 10 to 30 nm thick layer of silicon nitride is deposited, after the manufacture of the select gate, in a layer of heavily doped polycrystalline silicon. Next, the parts of the silicon nitride layer extending transversely to the surface are provided with spacers of silicon oxide. After etching away the silicon nitride, the spacers of silicon oxide remain at a distance of 10 to 30 nm from the select gate. While masking the select gate and said spacers, between which two 10 to 30 nm wide gaps are present, phosphor ions are implanted. After removal of the spacers and the underlying silicon nitride, an oxidation treatment is carried out, wherein a layer of silicon oxide is formed on the select gate, and an approximately 6 to 12 nm thick layer of tunnel oxide is formed on the surface next to the select gate. During this oxidation treatment, which is carried out at a high temperature, the phosphor ions diffuse in the silicon body and the connection region is formed. On the select gate of heavily doped polycrystalline silicon, the oxidation rate, using customary oxidation processes to form gate and tunnel oxides, is substantially twice the rate that can be achieved when use is made of less heavily doped monocrystalline silicon, and a 12 to 24 nm thick silicon oxide layer will be formed. In practice, the phosphor ions will diffuse approximately 200 nm below the select gate and below the spacers, resulting in an approximately 500 nm wide connection region.

The semiconductor device in accordance with the invention can be manufactured much more readily because the process steps that are necessary to form the connection region are avoided. The method of manufacturing the device in accordance with the invention is characterized in that the layer of insulating material is applied to the select gate wall extending substantially transversely to the surface in a thickness which, viewed along the surface, determines the distance between the select gate and the floating gate and enables a continuous channel to be formed between the source region and the drain region.

For the gate dielectric, which insulates the stacked gate structure from the active semiconductor region, use can be made of various materials. Advantageously, however, use is made of silicon oxide for the gate dielectric, which gate dielectric is hereinafter referred to as tunnel oxide. A desirable thickness for the tunnel oxide lies in the range between 8 and 10 nm. To form a layer having a thickness in the range between 30 and 70 nm on the wall of the select gate, and to form a layer having a thickness between 8 and 10 nm on the surface of the semiconductor body, in this case a silicon body, use can be made, for example, of a customary oxidation process to form a 60 nm thick layer on the select gate. As a result, an approximately 30 nm thick layer is formed on the surface. By means of an etching treatment, during which the select gate is covered by a mask, the thickness of the tunnel oxide formed can be reduced to the desired value. A simpler solution is obtained if the silicon body is subjected to an oxidation treatment wherein said silicon body is heated to a temperature in the range between 600 and 800° C. in a gas mixture of a non-oxidizing carrier gas and water vapor. It has been found that, under such conditions, the rate at which a layer of silicon oxide grows on heavily doped non-crystalline silicon is six times the growth rate that is achieved on lightly doped monocrystalline silicon. Thus, when a 8 to 10 nm thick layer of tunnel oxide is formed, a 50 to 60 nm thick layer of silicon oxide forms on the select gate.

As noted hereinabove, advantageously, the thickness of the layer of insulating material on top of the select gate is larger than the thickness of said layer of insulating material covering the select gate wall extending at least substantially transversely to the surface. This can be readily achieved by providing a stack of a conductive layer and an insulating layer, and patterning this stack so as to form the select gate in the conductive layer. Preferably, the insulating layer, which is provided on the conductive layer, is applied in a thickness above 100 nm.

These and other aspects of the invention will be apparent from and elucidated with reference to the embodiment(s) described hereinafter.

In the drawings:

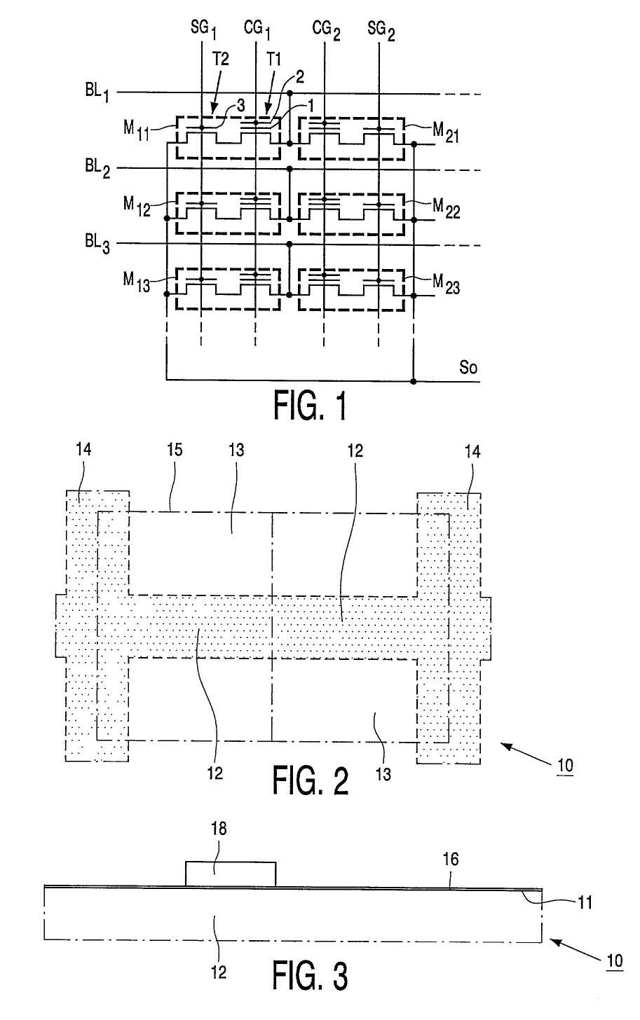

FIG. 1 shows an electrical circuit diagram of an EEPROM memory comprising an array of memory cells arranged in rows and columns, as formed in the semiconductor device in accordance with the invention,

FIG. 2 through FIG. 10 are diagrammatic, cross-sectional plan views of several stages in the manufacture of a first example of the semiconductor device in accordance with the invention, which is manufactured by means of the method in accordance with the invention,

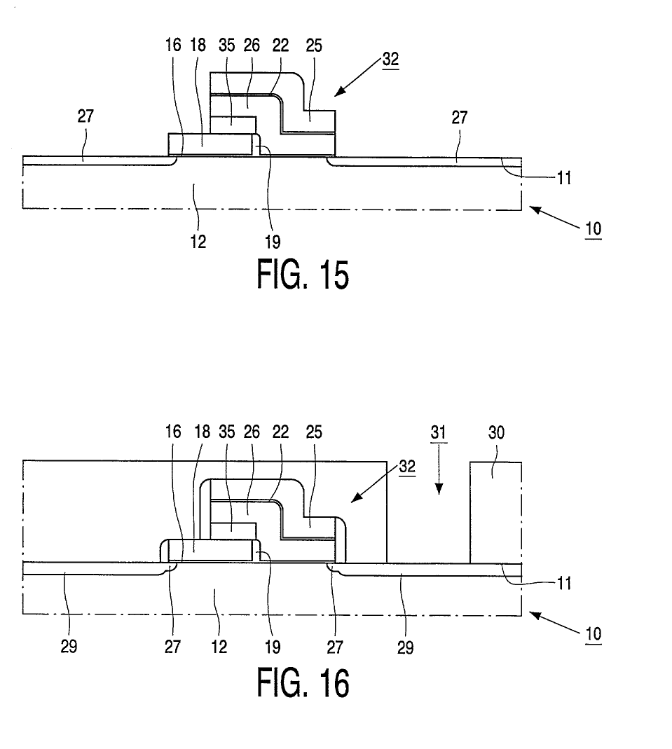

FIG. 11 through FIG. 16 are diagrammatic cross-sectional views of several stages in the manufacture of a second example of the semiconductor device in accordance with the invention, which is manufactured by means of the method in accordance with the invention.

FIG. 1 shows an electrical circuit diagram of an EEPROM memory comprising an array of memory cells Mᵢⱼ arranged in rows and columns, where i represents the number in the row and j represents the number in the column. Each memory cell comprises a memory transistor T1 having a floating gate 1 and a control gate 2 and, arranged in series therewith, a select transistor T2 with a select gate 3. The control gates 2 of a number of memory transistors T1, for example eight or more, are interconnected per column by lines CGj, the select gates 3 of the select transistors T2 are interconnected per column by lines SGj. Furthermore, the memory transistors T1 are interconnected per row by bit lines BLᵢ, and the transistors T2 are interconnected by a source line SO that is shared by a number of memory cells.

The EEPROM memory in accordance with the invention, which will be described in greater detail hereinafter, can be operated in various ways. Data can be written in the memory cells and erased from said memory cells by Fowler-Nordheim tunneling, or, alternatively, data can be written by injection of “hot electrons” and erased by Fowler-Nordheim tunneling. The following Tables show the voltages that can be applied to said lines in order to write data in one of the memory cells, in this case memory cell M₁l, erase data from a column of memory cells, in this case memory cells M₁ⱼ, and read the content of one memory cell, in this case M₁l.

In the first case:

| | CG₁ | SG₁ | BL₁ | CG_{2...j...} | SG_{2...j...} | BL_{2...i...} | SO |
|---|---|---|---|---|---|---|---|
| Writing | +12 V | 0 V | 0 V | 0 V | 0 V | +6 V | Open |
| Erasing | −12 V | 0 V | 0 V | 0 V | 0 V | 0 V | Open |
| Reading | +1 V | +3 V | +1 V | +1 V | 0 V | 0 V | 0 V |

In the second case:

| | CG₁ | SG₁ | BL₁ | CG_{2....j...} | SG_{2...j...} | BL_{2...i...} | SO |
|---|---|---|---|---|---|---|---|
| Writing | +10 V | +1,5 V | +5 V | 0 V | 0 V | 0 V | 0 V |
| Erasing | −12 V | 0 V | 0 V | 0 V | 0 V | 0 V | Open |
| Reading | +1 V | +3 V | +1 V | +1 V | 0 V | 0 V | 0 V |

It is to be noted that the memory transistor T1 has a threshold voltage of approximately +2 V during writing, and of approximately −2 V during erasing.

FIGS. 2 through 10 are diagrammatic, cross-sectional plan views of a few stages in the manufacture of a first example of the semiconductor device in accordance with the invention. Said Figures show, in a plan view, the manufacture of two juxtaposed memory cells and, in a cross-sectional view, the manufacture of the left memory cell.

As shown in FIG. 2, in a semiconductor body 10, for example a silicon body, active strip-shaped semiconductor regions 12 are formed at the location of the memory cells to be formed, which active strip-shaped semiconductor regions border on a surface 11 of the semiconductor body 10 and are bounded by field oxide regions 13. Said field oxide regions 13 also bound strip-shaped semiconductor regions 14 extending transversely to the strip-shaped active regions 12. The strip-shaped regions 14 are interconnected, outside the plane of the drawing, and form the above-mentioned common source line SO. In FIG. 2, the part of the surface 11 that is occupied by two memory cells is indicated by means of dot-dash lines 15. In this example, use is made of a customary, heavily doped silicon body which is provided with an epitaxially grown top layer which is comparatively lightly doped with approximately 10¹⁵ atoms per cc. In the top layer, the semiconductor regions 12 and 14 are formed. For the sake of simplicity, only this top layer is shown in the drawings of the silicon body 10.

As shown in FIG. 6, after the formation of the semiconductor regions 12 and 14, the surface 11 of the silicon body 10 is provided with a silicon oxide layer 16, in a customary manner by thermal oxidation of silicon bordering on the surface 11, which silicon oxide layer has a thickness between 5 and 10 nm, as a result of which the layer can suitably be used as a gate oxide of the select transistors T2. As shown in FIG. 3, on this layer of silicon oxide 16, a first system of mutually parallel strips 17 is subsequently formed in a first conductive layer, for example an approximately 150 nm thick layer of non-crystalline silicon, which is deposited on the layer of silicon oxide 16. The layer of non-crystalline silicon may be a layer of polycrystalline silicon or, alternatively, a layer of amorphous silicon. During the manufacture of the semiconductor device, where the semiconductor body is generally subjected several times to a treatment at a high temperature, said layer of amorphous silicon may convert to a layer of polycrystalline silicon. To form the strips, the layer of non-crystalline silicon is heavily n-type doped. As shown in FIG. 3, the strips 17 form, at the location of the active regions 12, the select gates 18 of the select transistors T2. Furthermore, the strips interconnect the select gates 18 of the select transistors T2 arranged in a column, and thereby form the lines SG.

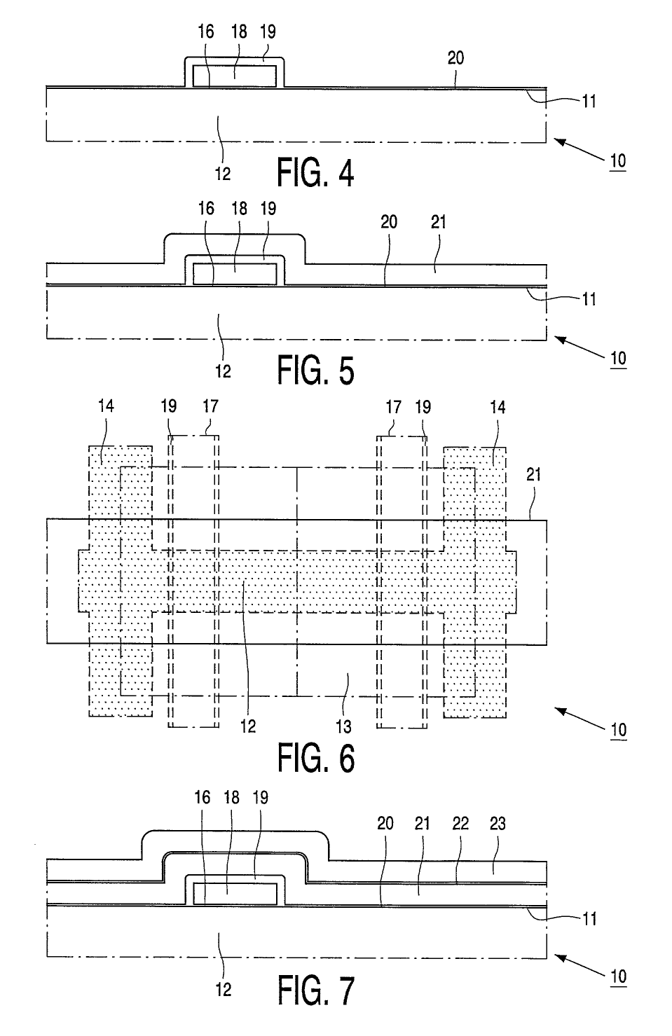

After the formation of the strips of non-crystalline silicon 17, an implantation of boron ions is carried out, while masking the strips, using a dose of 10¹² atoms per cm² to set the threshold voltage of the memory transistor T1 to be formed next to the select transistor T2. Subsequently, the parts of the silicon oxide layer 16 that are situated next to the strips 17 are removed and, as shown in FIG. 4, the select gate 18 is provided with a layer of an insulating material 19, in which process also a 8 to 10 nm thick silicon oxide layer 20 is formed on the surface 11 of the semiconductor body, next to the select gate 18, so that the layer can suitably be used as a tunnel oxide for the memory transistor.

Subsequently, a second conductive layer, for example a layer of n-type doped non-crystalline silicon, is deposited. As shown in FIGS. 5 and 6, strips 21 are formed in said layer, which extend in the direction of the active regions 12 and transversely to the strips 17 formed in the first layer of non-crystalline silicon. Next, as shown in FIG. 7, a layer of an intermediate dielectric 22 is deposited on the structure thus formed, which intermediate dielectric is composed, in this case, of an approximately 6 nm thick layer of silicon oxide, an approximately 6 nm thick layer of silicon nitride and an approximately 6 nm thick layer of silicon oxide, which are successively deposited. A third conductive layer 23, for example a layer of n-type doped non-crystalline silicon, is deposited on the layer of an intermediate dielectric 22.

In the third layer of non-crystalline silicon 23, strips 24 are formed, as shown in FIG. 10. The parts of the strips situated above the active regions 12 form the control gates 25 of the memory transistors T1. The control gates 25 of memory transistors arranged in columns are interconnected by the strips of non-crystalline silicon, so that said strips 24 form the lines CG of the memory.

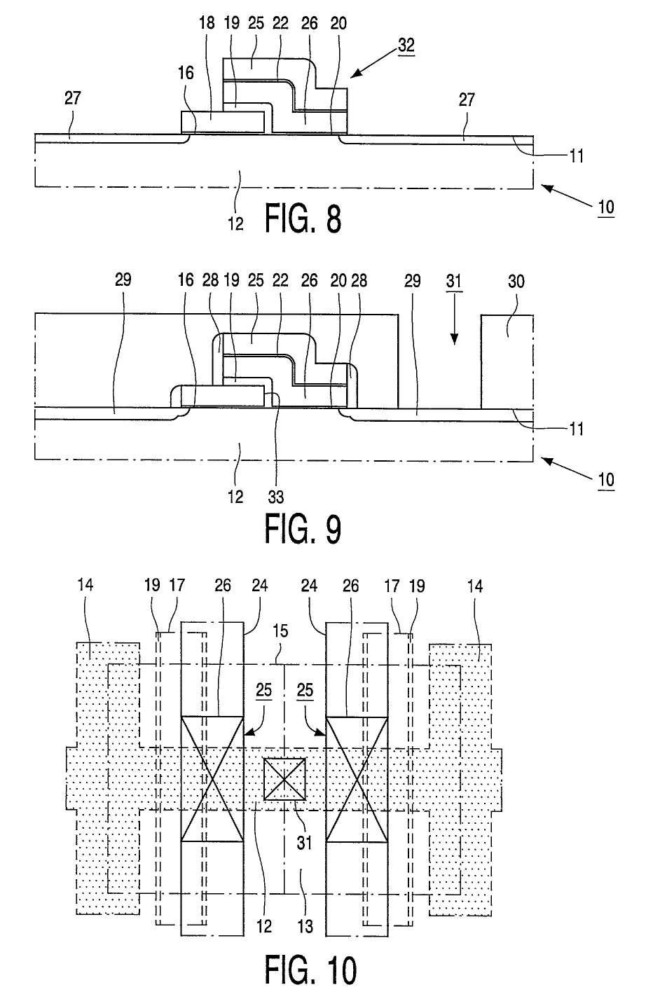

While masking these strips 24, as shown in FIG. 8, also the layer of intermediate dielectric 22, the underlying strips 21 formed in the second layer of non-crystalline silicon and the silicon oxide layers 19 and 20 are etched in accordance with a pattern. The remaining parts of the strips 21 formed in the second layer of non-crystalline silicon form the floating gates 26 of the memory transistors T1. Control gate 25 and floating gate 26 are separated from each other by the layer of intermediate dielectric.

Subsequently, a customary source-drain-extension implantation with 10¹³ arsenic atoms per cm² is carried out, after which the source-drain-extension regions 27 are formed, as shown in FIG. 8, by means of a thermal treatment. After the silicon oxide spacers 28 are formed in a customary manner on the edges of the exposed edges of the strips 17 and 24, the source-drain regions 29 are formed by an implantation of 10¹⁵ arsenic ions per cm² and a subsequent thermal treatment.

Finally, as shown in FIGS. 9 and 10, a layer of silicon oxide 30 is deposited and contact windows 31 are formed therein. The layer of silicon oxide 30 is provided with aluminum conductor tracks, not shown in said drawings, which make contact, in the contact holes 31, with the drain regions 29 of the memory transistors T1. These strips form the bit lines BL of the memory.

In this manner, as shown in FIGS. 9 and 10, a semiconductor device is formed comprising a semiconductor body 10, in this example a silicon body, including an active semiconductor region 12, which is arranged so as to border on a surface 11 of said semiconductor body, which semiconductor region is provided with an EEPROM memory comprising an array of memory cells ME arranged in rows and columns, and including a select transistor T2 having a select gate 18 of, in this example, noncrystalline-doped silicon, which is situated on a gate oxide layer 16 formed on the surface 11, and also including a memory transistor T1 having a stacked gate structure 32 with a floating gate 26 of, in this example, noncrystalline-doped silicon, a layer of intermediate dielectric 22 and a control gate 25 of, in this example, noncrystalline-doped silicon, which stacked gate structure (?) is situated on a tunnel oxide layer 20 formed on the surface 11 next to the select gate 18 and extends so as to be situated on top of the select gate 18 and covers the wall 33 thereof which extends at least substantially transversely to the surface, the stacked gate structure 32 being insulated from the select gate 18 by a layer of an insulating material 19.

The select gate 18 and the floating gate 26 are situated, viewed along the surface 11, at a distance from each other that is determined by the thickness of the layer of insulating material 19 which is present on the wall 33 of the select gate 18 and over which the stacked gate structure 32 extends. This thickness, which is such as to enable a continuous channel to be formed between the source region and the drain region, is preferably smaller than 70 nm, and preferably ranges between 30 and 50 nm. As a result, the inversion regions below the select gate 18 and below the floating gate 26, which inversion regions are formed during reading the memory cell, will merge so well that for reading the memory cell low voltages are sufficient. At such a small distance between the select gate and the floating gate, a negligibly small series resistance remains between said inversion regions. At a read voltage between 0.5 and 1 volt, the read current ranges between 30 and 50 μA, which can be readily detected in practice.

In order to reduce parasitic coupling between the select gate and the floating gate, the thickness of the layer of insulating material on top of the select gate preferably is larger than the thickness of said layer on the select gate wall that extends at least substantially transversely to the surface. As a result, parasitic coupling is reduced while the distance between the select gate and the floating gate can be maintained at a value enabling a continuous channel to be formed between the source region and the drain region. In practice, parasitic coupling is negligible if the layer of an insulating material on top of the select gate has a thickness above 100 nm, as in the case of the manufacture of the second example to be described of the semiconductor device in accordance with the invention.

In the manufacture of the first example, a semiconductor body 10, for example a silicon body, is provided with an active semiconductor region 12 bordering on a surface 11 of said semiconductor body, and, subsequently, with an array of memory cells ME arranged in rows and columns, including a select transistor T2 with a select gate 18 which is formed in a first conductive layer, for example a layer of non-crystalline silicon, which is deposited on a layer of gate oxide 16 formed on the surface 11, and including a memory transistor T1, which is arranged in series therewith, having a stacked gate structure 32 with a floating gate 26, intermediate dielectric 22 and control gate 25, which is formed in a second conductive layer 21, for example a layer of non-crystalline silicon, a layer of the intermediate dielectric 22 and a third conductive layer 23, for example a layer of non-crystalline silicon, which are successively deposited on the select gate 18 and on a juxtaposed tunnel oxide layer 20 formed on the surface 11. The gate structure 32 formed extends above the select gate 18 and covers the side wall 33 thereof which is directed transversely to the surface. The select gate 18 is provided with a layer of an insulating material 19 as a result of which the stacked gate structure 32 is insulated from the select gate 18.

Immediately after the formation of the select gate 18, as shown in FIG. 4, the tunnel oxide layer 20 is formed on the surface next to the select gate 18, and the side wall 33 of the select gate 18 is provided with a layer of silicon oxide 19 in a thickness enabling a continuous channel to be formed between the source region and the drain region, said thickness advantageously being below 70 nm, and preferably ranging between 30 and 50 nm. For the tunnel oxide layer 20, a desirable thickness ranges between 8 and 10 nm. In order to provide the wall 33 of the select gate 18 with a layer having a thickness between 30 and 70 nm and provide the surface with a layer having a thickness between 8 and 10 nm, for example, a layer having a thickness of 60 nm can be formed on the select gate using a customary oxidation process. As a result, an approximately 30 nm thick layer is formed on the surface. By means of an etch treatment, during which the select gate is covered with a mask, the thickness of the tunnel oxide formed can then be reduced to the desired value. A simpler solution is obtained if the silicon body is subjected to an oxidation treatment wherein the silicon body is heated to a temperature in the range between 600 and 800° C. in a gas mixture of a non-oxidizing gas, such as nitrogen, and water vapor. It has been found that, under such conditions, a silicon oxide layer grows on heavily doped non-crystalline silicon at a rate that is six times the rate of growth on lightly doped monocrystalline silicon. And, during the formation of an 8 to 10 nm thick tunnel oxide layer, a 50 to 60 nm thick silicon oxide layer forms on the select gate.

The memory with the memory cells ME described hereinabove can be manufactured on a very small part of the surface 11. The parts of the surface 11, indicated by means of dot-dash lines 15 in FIGS. 2, 6 and 10, which comprise two memory cells, have dimensions of 600 by 800 nm per memory cell when use is made of a “0.18 μm process” (a technology enabling minimum details of 0.18 μm to be realized).

FIGS. 11 through 16 are diagrammatic, cross-sectional views of a few stages in the manufacture of a second example of the semiconductor device in accordance with the invention. In these Figures, where possible, the same reference numerals are used as in the preceding Figures.

In this example, prior to the formation of the strips 17 in the first conductive layer, which is for example a layer of a non-crystalline silicon, this first conductive layer is covered with an insulating layer, for example a layer of silicon oxide, after which the strips 17 are formed in the first conductive layer, during which treatment the insulating layer, which is provided on the first conductive layer, is provided with a pattern. In this manner, the select gate 18 shown in FIG. 11 is formed, which is provided with an insulating top layer 35. This top layer 35, of course, also extends over the strips 17.

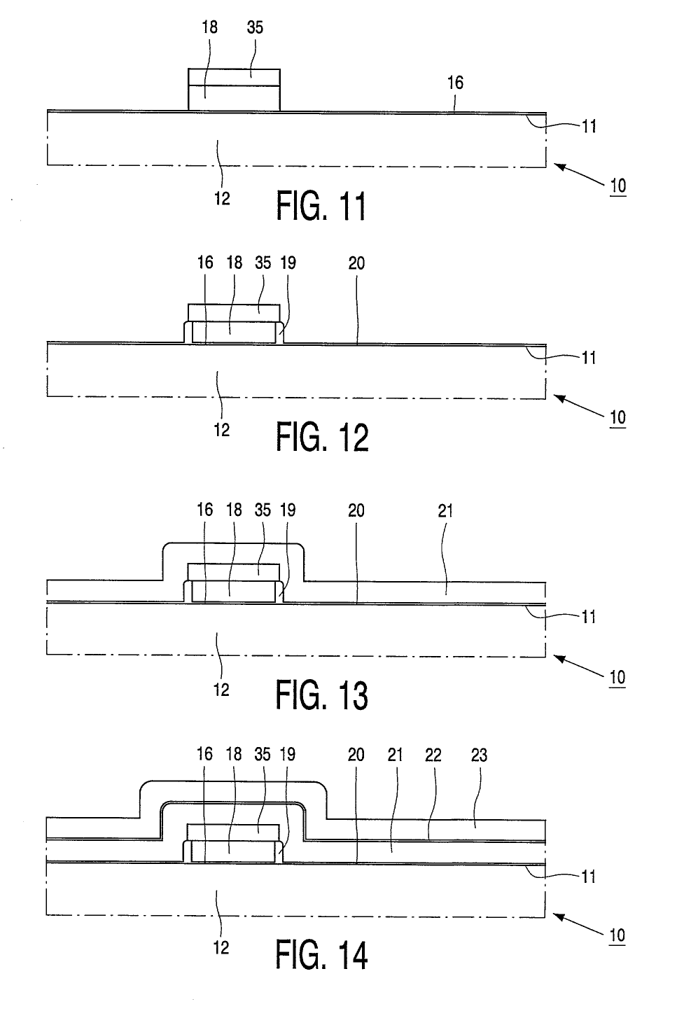

Subsequently, as shown in FIG. 12, after the removal of the part of the silicon oxide layer 16 that is situated next to the select gate, and after the above-mentioned implantation of boron ions, the above-mentioned oxidation treatment is carried out, wherein the side wall 33 of the select gate 18 is provided with an approximately 40 nm thick layer of silicon oxide 19 and the surface is provided with an approximately 8 nm thick tunnel oxide layer 20.

As shown in FIG. 13, after the formation of the insulating layers 19 and 20, the strips 21 are formed, just like in the first example, in the second conductive layer, for example a layer of non-crystalline silicon, after which, as shown in FIG. 14, the layer of intermediate dielectric 22 and the third conductive layer 23, for example a layer of non-crystalline silicon, are deposited. Next, the stacked gate structure 32 is formed comprising the floating gate 26 and the control gate 25. After the formation of the source and drain extension regions 27, the spacers 28 are formed, after which the source and drain regions 29 are formed and the whole is covered with the silicon oxide layer 30 wherein the contact windows 31 are etched.

The silicon oxide layer 35 on top of the select gate 18 can be readily provided in a thickness exceeding that of the silicon oxide layer 19 provided on the wall 33 of the select gate 18. Preferably, the layer 35 has a thickness above 100 nm. As a result, parasitic coupling between the select gate 18 and the floating gate 26 is negligibly small.

1. A semiconductor device comprising a semiconductor body (10) including an active semiconductor region (12) which borders on a surface (11) of said semiconductor body and which is provided with a non-volatile memory cell comprising a source region and a drain region (29), a select gate (18), and a stacked gate structure (32) comprising a floating gate (26) and a control gate (25), which stacked gate structure projects beyond the select gate and covers the wall (33) of the select gate that extends at least substantially transversely to the surface, said stacked gate structure being insulated from the select gate by a layer of an insulating material (19, 35), characterized in that the select gate and the floating gate, viewed along the surface, are situated at a distance from each other that is determined by the thickness of the layer of insulating material applied to the wall of the select gate, said wall extending substantially transversely to the surface, and said thickness enabling a continuous channel to be formed between the source region and the drain region.

2. A semiconductor device as claimed in claim 1, characterized in that the thickness of the layer of insulating material against the select gate wall extending at least substantially transversely to the surface is below 70 nm.

3. A semiconductor device as claimed in claim 1 or 2, characterized in that the thickness of the layer of insulating material against the select gate wall extending at least substantially transversely to the surface lies in the range between 30 and 50 nm.

4. A semiconductor device as claimed in any one of the preceding claims, characterized in that the select gate, viewed along the surface, is provided on the side of the stacked gate structure facing the source region.

5. A semiconductor device as claimed in any one of the preceding claims, characterized in that the layer of insulating material on top of the select gate has a larger thickness than the layer of insulating material against the select gate wall extending at least substantially transversely to the surface.

6. A semiconductor device as claimed in claim 5, characterized in that the layer of insulating material on top of the select gate has a thickness above 100 nm.

7. A method of manufacturing a semiconductor device comprising a non-volatile memory cell, wherein
a semiconductor body (10) is provided, at a surface (11), with an active semiconductor region (12);
a select gate (18) is provided, which select gate is insulated from the active semiconductor region;
the select gate is provided with a layer of an insulating material (19, 35);
a stacked gate structure (32) comprising a floating gate (26) and a control gate (25) is provided, which stacked gate structure extends above the select gate and covers the select gate wall (33) extending at least substantially transversely to the surface, which stacked gate structure is insulated from the select gate by means of the layer of insulating material and insulated from the active semiconductor region by means of a gate dielectric (20);
the active semiconductor region is provided with a source region and a drain region (29), the select gate and the stacked gate structure being used as a mask; characterized in that
the layer of insulating material is applied to the select gate wall extending at least substantially transversely to the surface in a thickness which, viewed along the surface, determines the distance between the select gate and the floating gate and enables a continuous channel to be formed between the source region and the drain region.

8. A method as claimed in claim 7, characterized in that the layer of insulating material is applied to the select gate wall extending at least substantially transversely to the surface in a thickness below 70 nm.

9. A method as claimed in claim 7 or 8, characterized in that the layer of insulating material is applied to the select gate wall extending at least substantially transversely to the surface in a thickness ranging between 30 and 50 nm.

10. A method as claimed in any one of the claims 7 through 9, characterized in that prior to the provision of the stacked gate structure, the semiconductor body is subjected to a thermal oxidation treatment, in the course of which the select gate is provided with the layer of insulating material and the active semiconductor region is provided with the gate dielectric in order to insulate the stacked gate structure from the active semiconductor region.

11. A method as claimed in any one of the claims 7 through 10, characterized in that the select gate is formed by providing a stack of a conductive layer provided with an insulating layer, which stack is patterned so as to form the select gate in the conductive layer.

12. A method as claimed in claim 11, characterized in that the insulating layer, which is applied to the conductive layer, is provided in a thickness above 100 nm.
